(19) United States
(12) Patent Application Publication
(10) Pub. No.: US 2013/0240920 A1
(43) Pub. Date: Sep. 19, 2013

(54) MULTI-DIRECTION BULB-TYPE LAMP

(71) Applicants: Li-Fan LIN, Taoyuan County (TW); Wen-Chia LIAO, Taoyuan County (TW); Ching-Chuan SHIUE, Taoyuan County (TW); Shih-Peng CHEN, Taoyuan County (TW)

(72) Inventors: Li-Fan LIN, Taoyuan County (TW); Wen-Chia LIAO, Taoyuan County (TW); Ching-Chuan SHIUE, Taoyuan County (TW); Shih-Peng CHEN, Taoyuan County (TW)

(73) Assignee: DELTA ELECTRONICS, INC., Taoyuan County (TW)

(21) Appl. No.: 13/563,997

(22) Filed: Aug. 1, 2012

(30) Foreign Application Priority Data
Mar. 19, 2012 (TW) 101109398

(51) Int. Cl. H01L 27/15

(52) U.S. Cl. 257/89; 257/E27.12

(57) ABSTRACT

A multi-directional bulb-type lamp is disclosed. The multi-directional bulb-type lamp includes a carrying body, a flexible substrate, and a plurality of LED dies. The flexible substrate is a substrate extending toward multi-directions and attached to the carrying body along a surface thereof. The LED dies are directly disposed on the flexible substrate and electrically connected thereto. Whereby, structures of the bulb-type lamp will be simplified for easy assembly, and multi-directional lighting will be reached.

### BACKGROUND OF THE INVENTION

1. Field of the Invention

The present invention relates to a light emitting diode (LED) lamp holder, especially to a multi-directional lamp holder.

2. Description of Related Art

In recent, because technologies of light emitting diode (LED) have rapid development and gradually maturity, and LED has advantages of lower power consumption, long lifetime, small volume and lower responsive time, LED is widely used in all of lighting field. However, LED is a spot lighting with single light and the illumination range is very small, so that in the general use, it is usually combining multiple LEDs to form a LED lamp module for increasing illumination range and brightness, and for mixing different colors of light to form light in need.

Reference is made to FIG. 1, which is an exploded view of a related art LED lamp. The LED lamp 1′ includes a circuit board 10′, a plurality of LED elements 20′, and a housing 30′. The LED elements 20′ arranged in a matrix manner are positioned on the circuit board 10′, and the circuit board 10′ is combined to the housing 30.′ The LED lamp 1′ emits light toward only one direction. In order to reach an illuminant effect of full-angle (multi-directions), the housing 30′ may be combined with multiple divided circuit boards 10′, and the circuit boards 10′ are positioned in multiple directions to fulfill a lamp with full angle illumination.

Through the LED lamp 1′ mentioned above can achieve multi-directional illumination, the assembly is time-cost. Besides, the LED elements 20′ are fixed to the circuit board 10′ by lead frame combination which causes higher thermal resistance, larger spacing limitation, and high cost. Furthermore, the illumination of the LED elements 20′ isn't uniform because the LED elements 20′ are disposed on different circuit boards 10′ with lead frame.

### SUMMARY OF THE INVENTION

It is an object of the present invention to provide a multi-directional bulb-type lamp which can be simplified for easy assembly, and reach multi-directional lighting.

It is another object of the present invention to provide a multi-directional bulb-type lamp to reach low thermal resistance, smaller spacing limitation, and with uniform illuminant effect.

Accordingly, the multi-directional bulb-type lamp according to one aspect of the present invention comprises a carrying body, a flexible substrate and a plurality of LED dies. The flexible substrate is a substrate extending toward multi-directions. The flexible substrate is attached to the carrying body along the surface of the carrying body. The LED dies are directly disposed on the flexible substrate and electrically connected to the flexible substrate.

Compare to the related art, the bulb-type lamp of the present invention includes a carrying body and a flexible substrate, the flexible substrate extending toward multi-directions and attached to the carrying body along a surface thereof. Wherein, the carrying body may be ball-shape or polyhedron, and the flexible substrate includes a central disposing area and a plurality of lateral disposing areas. The lateral disposing areas may be bar-shape or other configuration can attached to the surface of the carrying body and reach the illuminant effect of multi-directional. Besides, the LED dies of the bulb-type lamp of the present invention are disposed on the same flexible substrate without lead frame, thus can reduce color difference mentioned in the related art, and reach uniform colors, reduce the difficulty of assembling different circuit board, and increase utility.

### BRIEF DESCRIPTION OF DRAWINGS

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIG. 1 is a related art LED bulb-type lamp.

FIG. 2 is a cross sectional view of a multi-directional bulb-type lamp according to a first embodiment of the present invention.

FIG. 3 is an exploded perspective view of the multi-directional bulb-type lamp according to the first embodiment of the present invention.

FIG. 4 is an assembly view of the multi-directional bulb-type lamp according to the first embodiment of the present invention

FIG. 5 is a schematic view of the arrangement of the LED dies according to the first embodiment of the present invention.

FIG. 6 is a cross sectional view of the combination of the LED dies and the flexible substrate according to a second embodiment of the present invention.

FIG. 7 is a cross sectional view of the combination of the LED dies and the flexible substrate according to a third embodiment of the present invention.

FIG. 8 is a cross sectional view of the combination of the LED dies and the flexible substrate according to a forth embodiment of the present invention.

FIG. 9 is a planer view of a flexible substrate according to a second embodiment of the present invention.

FIG. 10 is an assemble view of the flexible substrate and a carrying body according to the second embodiment of the present invention.

FIG. 11 is a planar view of a flexible substrate according to a third embodiment of the present invention.

FIG. 12 is an assembly view of the flexible substrate and a carrying body according to the third embodiment of the present invention.

FIG. 13 is a planer view of a flexible substrate according to a forth embodiment of the present invention.

FIG. 14 is an assembly view of the flexible substrate and a carrying body according the forth embodiment of the present invention.

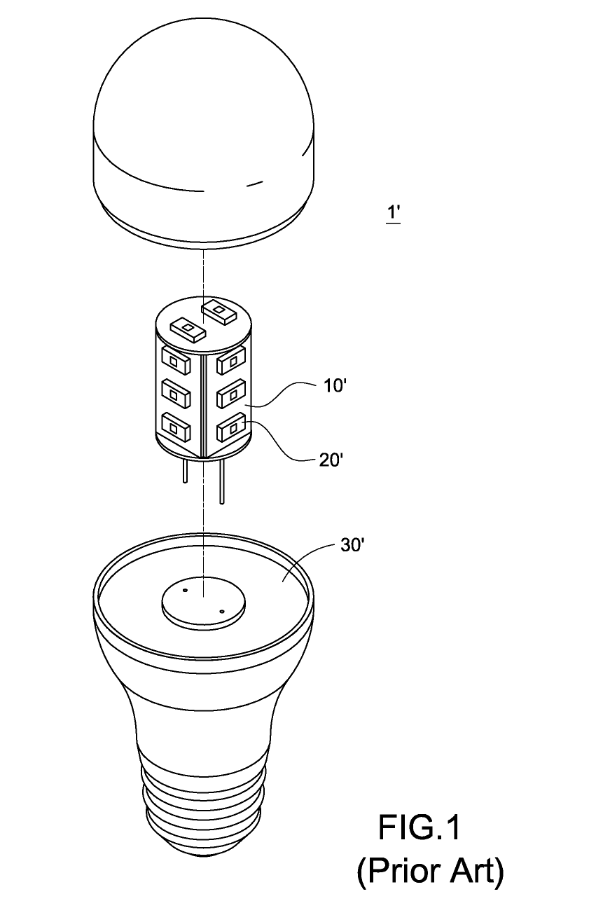

### DETAILED DESCRIPTION OF THE INVENTION

Reference will now be made in detail to the present embodiments of the invention, examples of which are illustrated in the accompanying drawings.

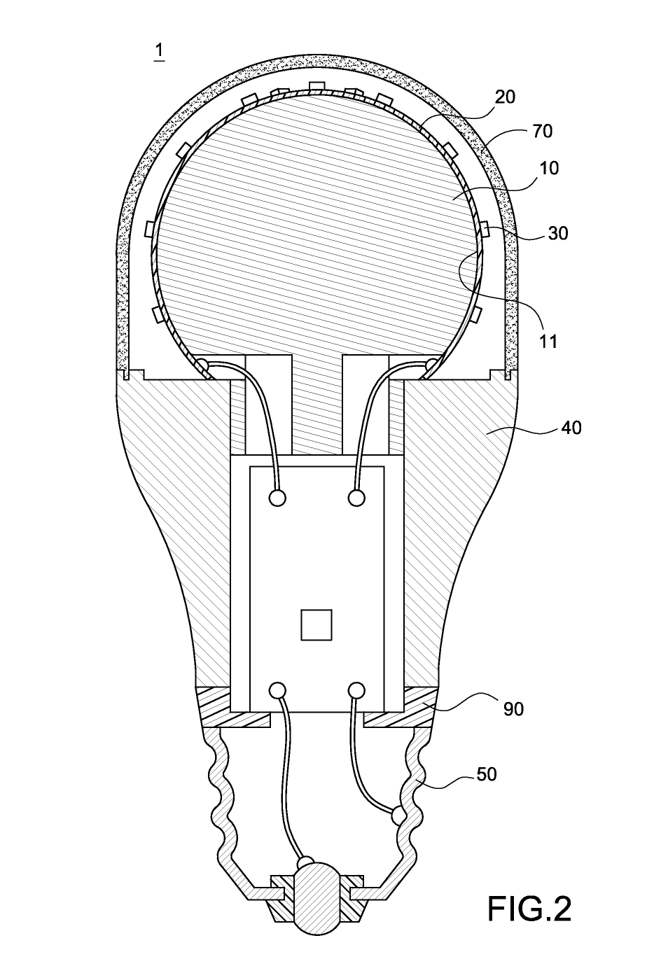

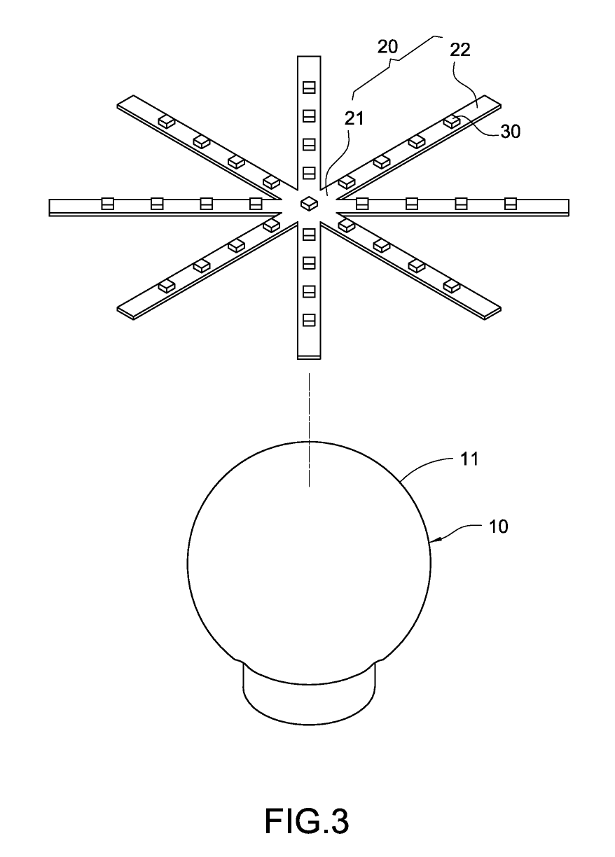

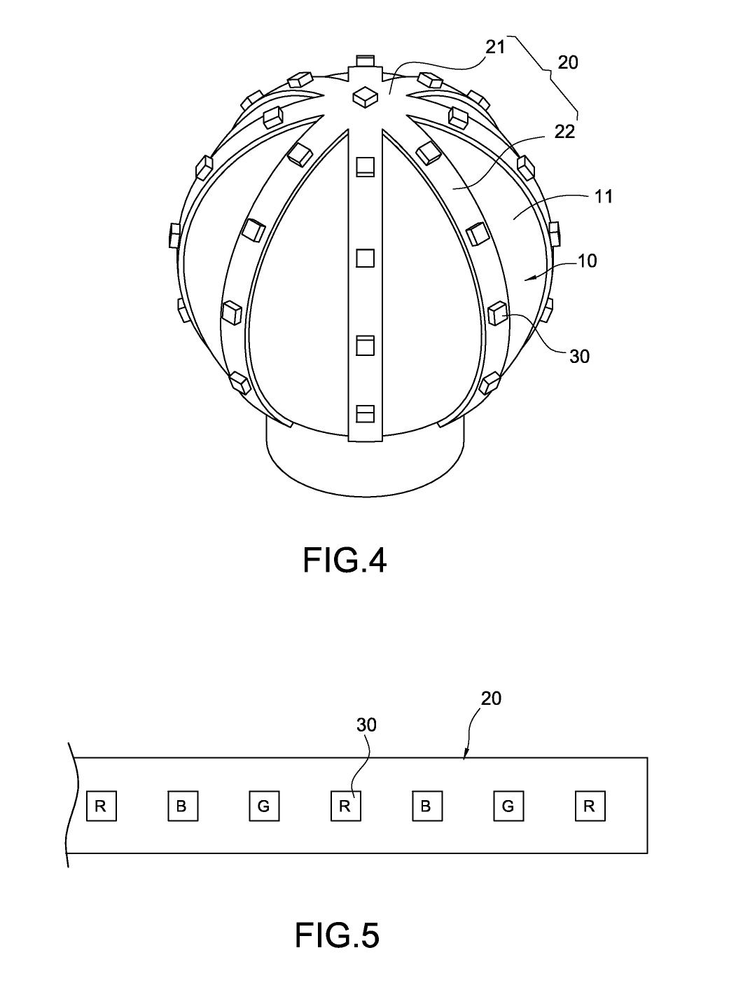

Referenced is made to FIG. 2, FIG. 3 and FIG. 4. FIG. 2 is a cross sectional view of a multi-directional bulb-type lamp according to a first embodiment of the present invention, FIG. 3 is exploded perspective of the multi-directional bulb-type lamp according to the first embodiment of the present invention, and FIG. 4 is an assembly view of the multi-directional bulb-type lamp according to the first embodiment of the present invention. The multi-directional bulb-type lamp 1 includes a carrying body 10, a flexible substrate 20, a plurality of light emitting diode (LED) dies 30, a heat dissipating body 40 and a bulb base 50. The carrying body 10 and the heat dissipating body 40 can be made of the same material and in one-piece form.

The carrying body 10 is made of material with heat conduction, and may be solid body or shelly body. In this embodiment, the carrying body 10 is substantially of ball-shape and has a spherical surface 11, so that the flexible substrate 20 can attach to the carrying body 10 along the spherical surface 11.

The flexible substrate 20 is a substrate extending toward multiple directions, and attached to the carrying body 10 along the surface of the carrying body 10. The flexible substrate 20 may be a flexible printed circuit board (FPC), a chip on flex (COF) tape or other substrate with flexibility. The flexible substrate 20 includes a central disposing area 21 and a plurality of lateral disposing areas 22 extending outwardly from the central disposing area 21. In this embodiment, each lateral disposing area 22 is of bar-shape. In addition, the lateral disposing areas 22 are spaced from each other and arranged in a radial manner.

The LED dies 30 are directly disposed on the flexible substrate 20, and electrically connected to the flexible substrate 20 by wire bonding or die bonding. The heat dissipating body 40 is physically connected to the carrying body 10 for dissipating heat generated by the flexible substrate 20 and the LED dies 30. In addition, the carrying body 10 is physically connected to the bulb base 50, and an isolated pad 90 is disposed between the bulb base 50 and the heat dissipating body 40, thus completing the assemble of the multi-directional bulb-type lamp.

Referred is made to FIG. 5, which is a schematic view of the arrangement of the LED dies according to the first embodiment of the present invention. The LED dies 30 are directly disposed on the flexible substrate 20. The LED dies 30 may only have single color or have two or more different colors. For example, the LED dies 30 include two or more LED dies 30 with red color R, green color G and blue color B. A color which is in need will be generated by mixing lights generated by the LED dies 30.

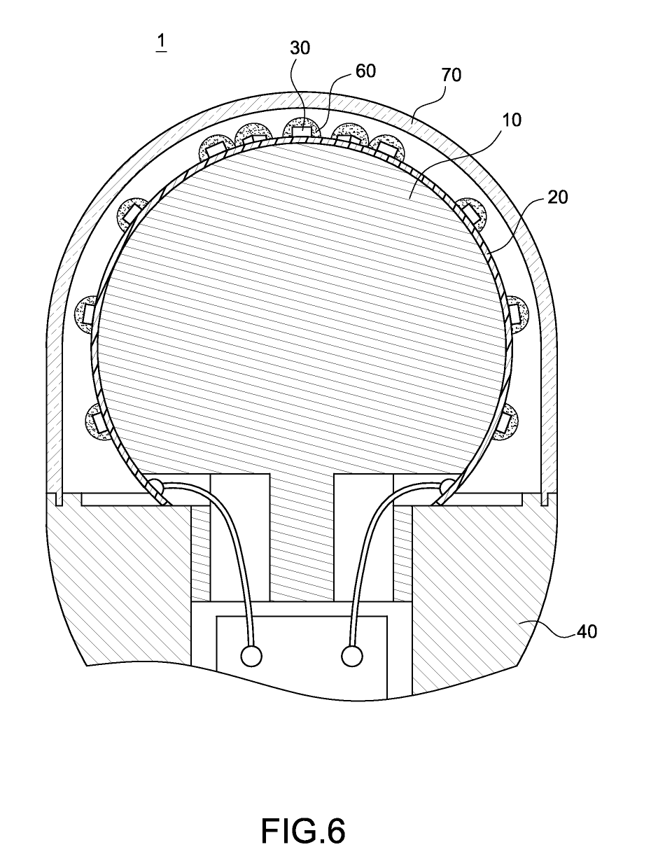

Referred is made to FIG. 6 to FIG. 8, which are cross sectional views for the combination of the LED dies and flexible substrate in accordance with some embodiments of the present invention. The multi-directional bulb-type lamp 10 further includes a first light transmitting layer 70 and a second light transmitting layer 60. The first light transmitting layer 70 and the second light transmitting layer 60 may further include a wavelength converting material. The wavelength converting material may be mixed into the first light transmitting layer 70 or the second light transmitting layer 60, or coated on an external surface of the first light transmitting layer 70. The wavelength converting material may be phosphor, quantum well film or quantum dot phosphor.

The first light transmitting layer 70 and the second light transmitting layer 60 are made of PMMA, PC, PP, epoxy, silicone, glass and other material with light transparency. The first light transmitting layer 70 diffuses light generated by the LED dies 30 and uniformly mixes lights generated by the LED dies 30.

FIG. 6 shows the combination of the LED dies and the flexible substrate according to a second embodiment of the present invention. Each LED die 30 is covered with the second light transmitting layer 60, and the LED dies 30 are arranged in unequal intervals. However, the above arrangement is only exemplary, and other arrangements are within the scope of the present disclosure. In addition, the first light transmitting layer 70 is physically connected to the heat dissipating body 40 and covers the LED dies 30.

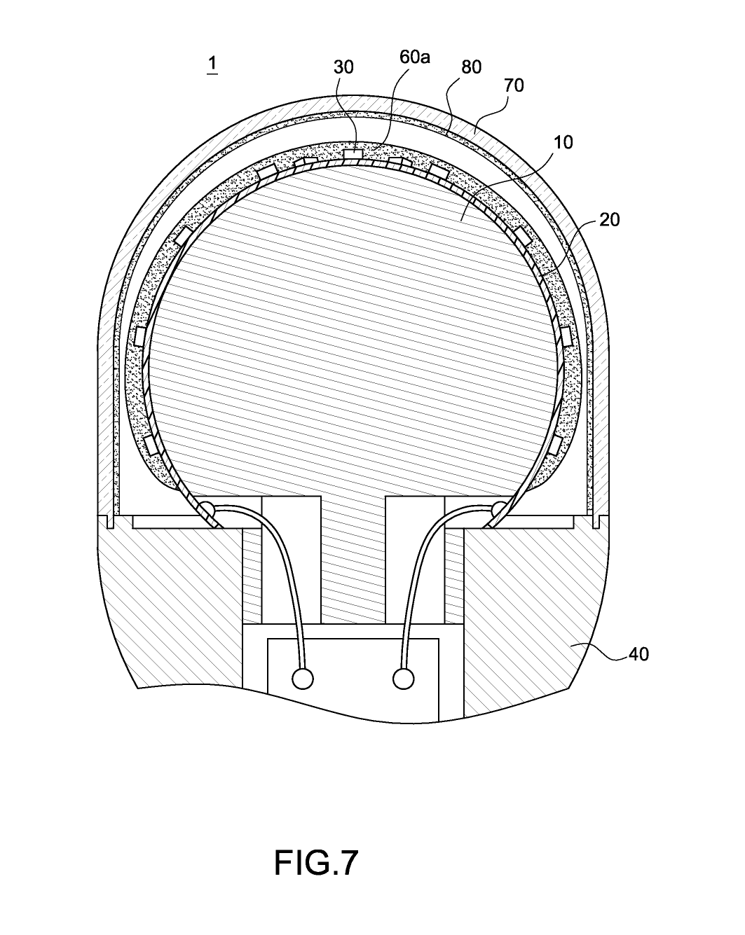

FIG. 7 shows the combination of the LED dies and the flexible substrate according to a third embodiment of the present invention. This embodiment is similar to that of embodiment shown in the FIG. 6, and the different is that the multi-directional bulb-type lamp 1 further includes a wavelength converting layer 80. The wavelength converting layer 80 is combined with the first light transmitting layer 70 for converting light generated by the LED dies 30 into another light with color different from the original color. In this embodiment, the wavelength converting layer 80 is combined with an internal surface of the first transmitting layer 70. In addition, another difference between FIG. 6 and FIG. 7 is that the second light transmitting layer 60a covers the LED dies 30 integrally.

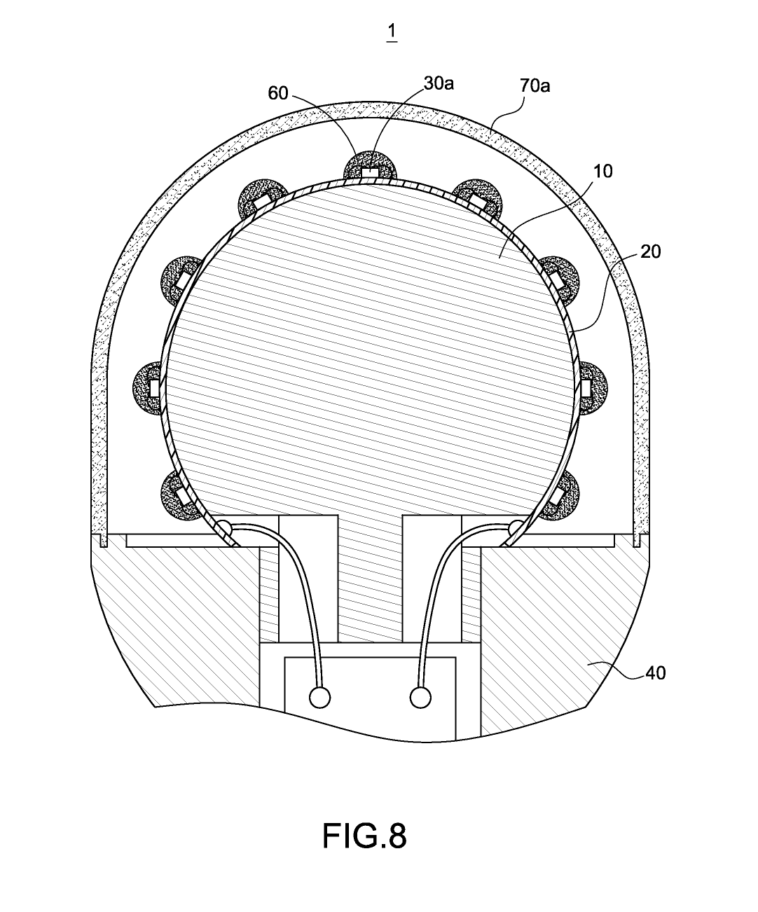

FIG. 8 shows the combination of the LED dies and the flexible substrate according to a forth embodiment of the present invention. This embodiment is similar to that of embodiment shown in the FIG. 6, and the different is that the LED dies 30a is electrically connected to the flexible substrate 20 by wire bonding, and the first light transmitting layer 70a further includes a wavelength converting material.

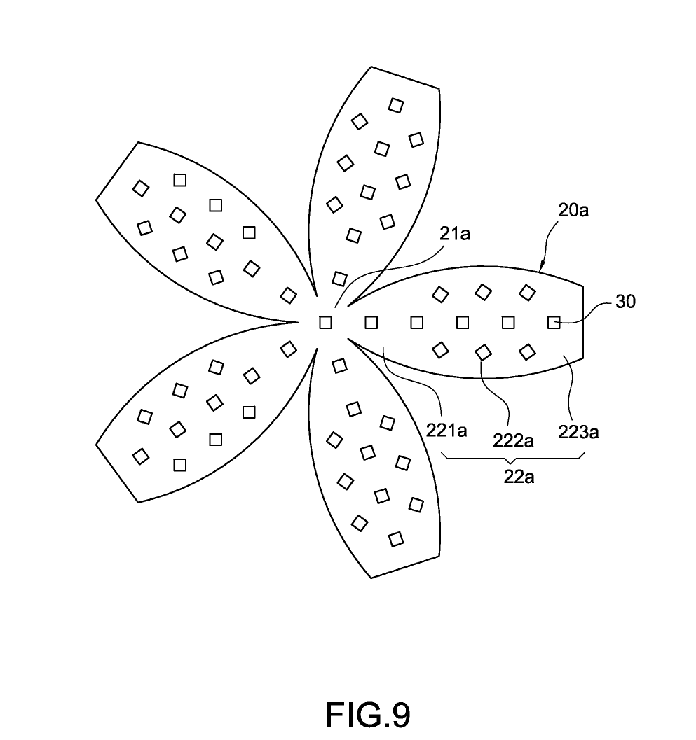

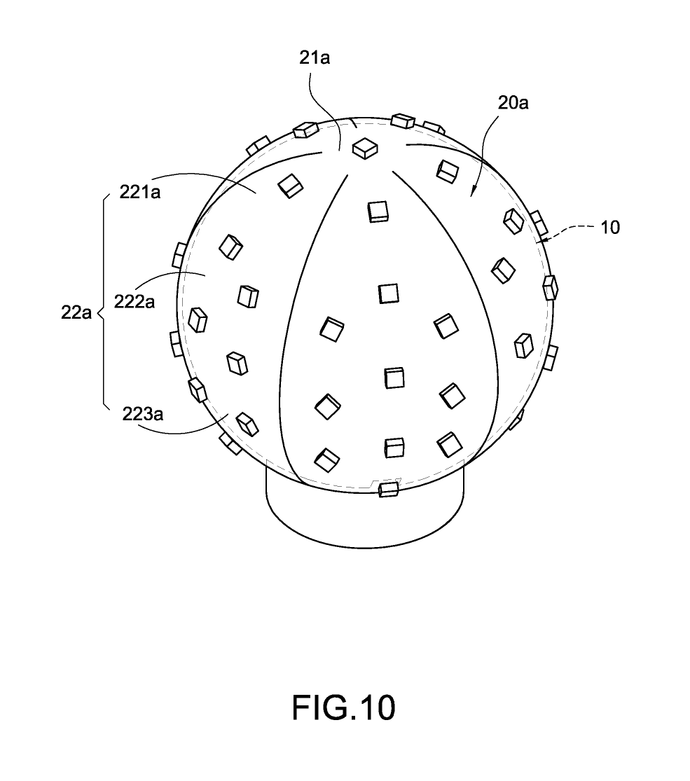

Referenced is made to FIG. 9 and FIG. 10, FIG. 9 is a planer view of a flexible substrate according to a second embodiment of the present invention, and FIG. 10 is an assemble view of the flexible substrate and a carrying body according to the second embodiment of the present invention. In this embodiment, the flexible substrate 20a includes a central disposing area 21a and a plurality of lateral disposing areas 22a extending outwardly from the central disposing area 21a. The lateral disposing areas 22a are spaced from each other and arranged in a radial manner. The flexible substrate 20a is similar to that of first embodiment mentioned above, and the different is that the lateral disposing area 22a includes a front section 221a extending from the central disposing area 21a, a middle section 222a connected with the front section 221a and a back section 223a connected to the middle section 222a. The configuration of the lateral disposing area 22a is gradually broadened from the front section 221a to the middle section 222a, and is gradually straitened form the middle section 222a to the back section 223a. Besides, a plurality of LED dies 30 are disposed on the flexible substrate 20a. The lateral disposing areas 22a are attached to the surface of carrying body 10a after the central disposing area 21a is disposed on the top of the carrying body 10a, so that the flexible substrate 20a is attached to the external surface of the carrying body 10a and lamp achieves multi-directionally illuminant effect. In addition, different sections may dispose different amount of LED dies 30a for controlling lighting amount and colors in different directions.

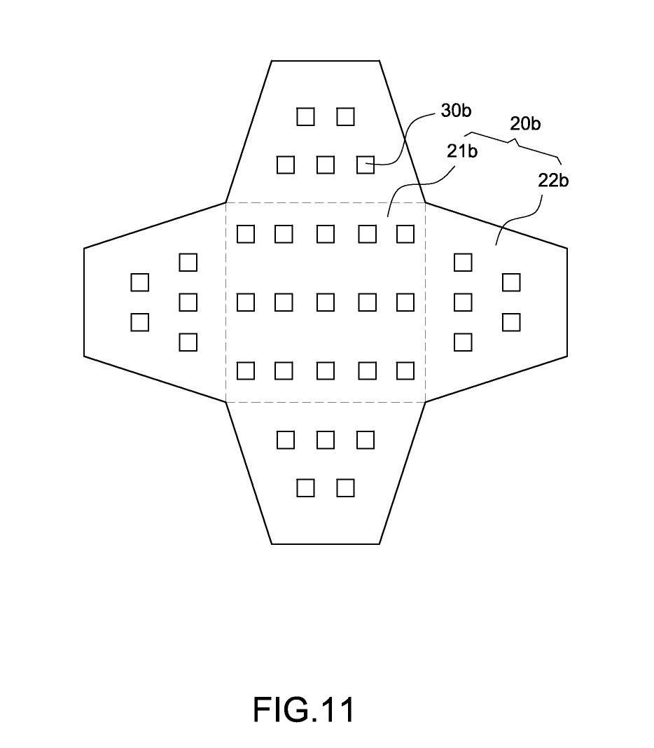

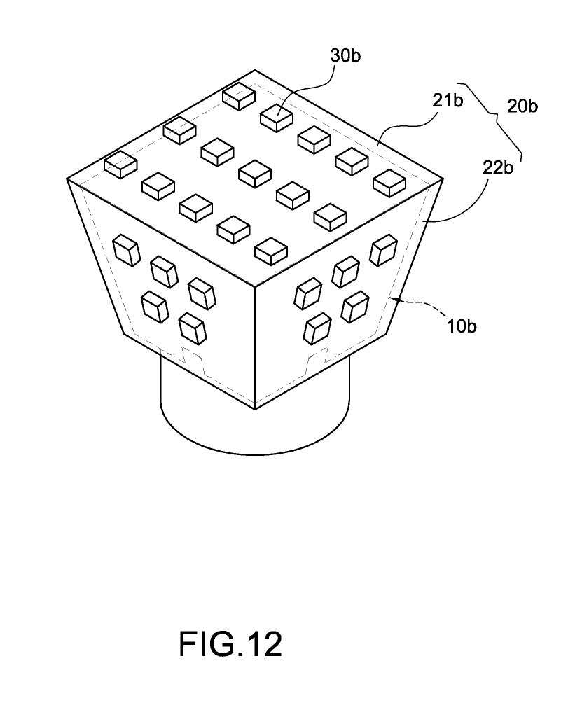

Referenced is made to FIG. 11 and FIG. 12, FIG. 11 is a planar view of a flexible substrate according to a third embodiment of the present invention, and FIG. 12 is an assembly view of the flexible substrate and a carrying body according to the third embodiment of the present invention. In this embodiment, the flexible substrate 20b includes a central disposing area 21b and a plurality of lateral disposing areas 22b extending outwardly from the central disposing area 21b. The flexible substrate 20b is similar to that of first embodiment mentioned above, and the different is that the central disposing area 21b is of rectangular-shape, each lateral disposing area 22b is extending outwardly from a side of the central disposing area 21b and of trapezoid-shape, and the carrying body 10b is a tetragon pillar. The central disposing area 21b is orientated on a top surface of the carrying body 10b after disposing a plurality of LED dies 30b on the central disposing area 21b and the lateral disposing areas 22b, and then the lateral disposing areas 22b are respectively attached to side-surfaces of the carrying body 22b, so that the lamp can achieve multi-directionally illuminant effect.

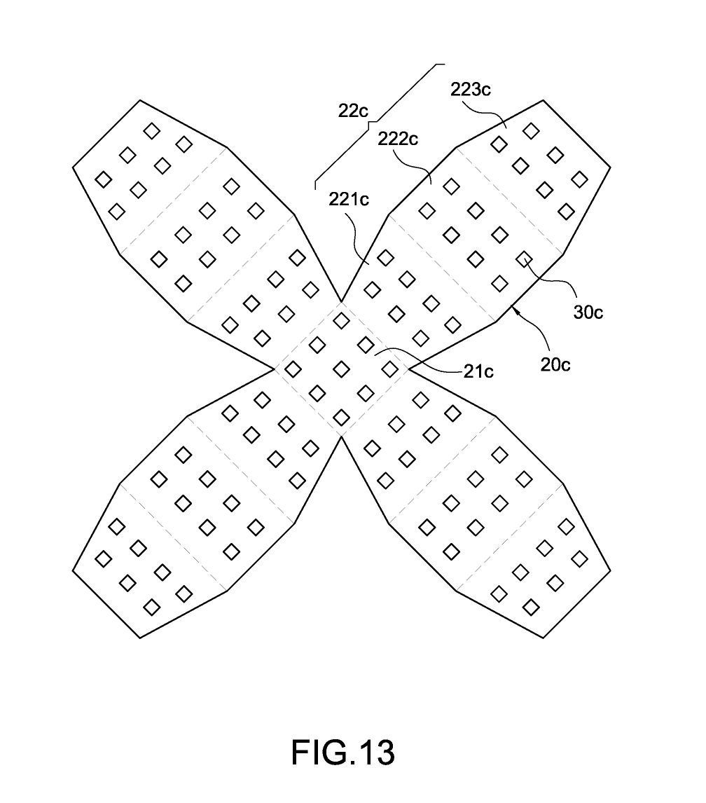

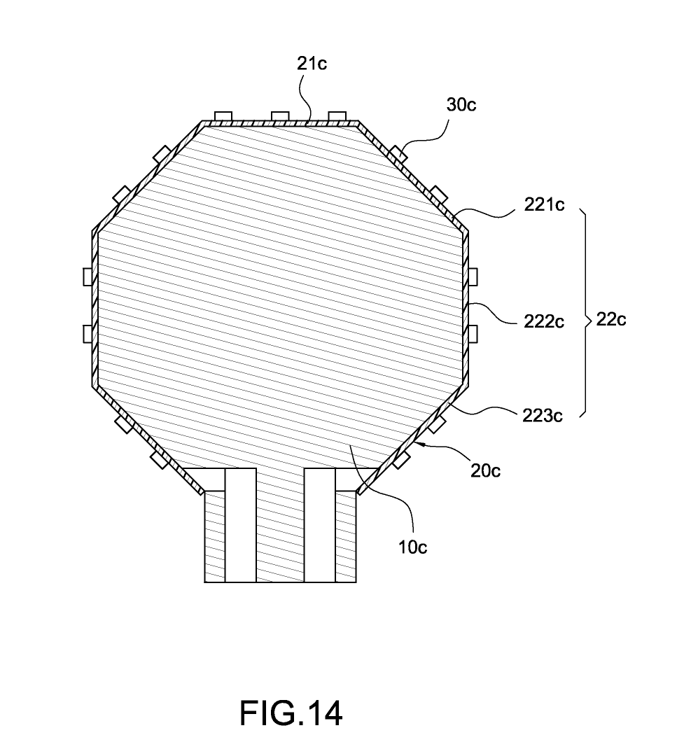

Referenced is made to FIG. 13 and FIG. 14, FIG. 13 is a planer view of a flexible substrate according to a forth embodiment of the present invention, and FIG. 14 is an assembly view of the flexible substrate and a carrying body according the forth embodiment of the present invention. In this embodiment, the flexible substrate 20c includes a central disposing area 21c and a plurality of lateral disposing areas 22c extending outwardly from the central disposing area 21c. The flexible substrate 20c is similar to that of first embodiment mentioned above, and the different is that the central disposing area 21c is of rectangular-shape, and each lateral disposing area 22c includes a front section 221c extending from the central disposing area 21c, a middle section 222c connected with the front section 221c and a back section 223c connected to the middle section 222c. In more particularly, the front section 221c is a section with trapezoid-shape, the middle section 222c is a section with rectangular-shape, and the back section 223c is another section with trapezoid-shape and symmetrical to the front section 221c. In addition, the carrying body 10c is a polyhedron. After disposing the LED dies 30c on the flexible substrate 20c, such that the central disposing area 21c and the lateral disposing areas 22c (including the front section 221c, middle section 222c and back section 223c) are attached to the surfaces of the carrying body 10c, and then multi-directionally (or multi-angles) illuminant effect can be achieved.

Although the present invention has been described with reference to the preferred embodiment thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

What is claimed is:

1. A multi-directional bulb-type lamp, comprising:
a carrying body;
a flexible substrate, being a substrate extending toward multiple directions, the flexible substrate attached to the carrying body along a surface of the carrying body; and
a plurality of light emitting diode (LED) dies directly disposed on the flexible substrate and electrically connected to the flexible substrate.

2. The multi-directional bulb-type lamp in claim 1, wherein the carrying body has a spherical surface and the flexible substrate is attached to the carrying body along the spherical surface.

3. The multi-directional bulb lamp holder in claim 2, wherein the flexible substrate comprises a central disposing area and a plurality of lateral disposing areas extending outwardly from the central disposing area.

4. The multi-directional bulb lamp holder in claim 3, wherein each lateral disposing area is of bar-shape.

5. The multi-directional bulb lamp holder in claim 3, wherein each lateral disposing area comprises a front section extending from the central disposing area, a middle section connected to the front section and a back section connected to the middle section, each lateral disposing area is gradually broadened from the front section to the middle section, and is gradually straitened form the middle section to the back section.

6. The multi-directional bulb lamp holder in claim 3, wherein the central disposing area is of rectangular-shape, each lateral disposing area is extending outwardly from a side of the central disposing area and of trapezoid-shape.

7. The multi-directional bulb lamp holder in claim 3, wherein the central disposing area is of rectangular-shape, the front section is a trapezoid section, the middle section is a rectangular section, and the back section is another trapezoid section symmetrical to the front section.

8. The multi-directional bulb lamp holder in claim 1, wherein the flexible substrate is a flexible printed board.

9. The multi-directional bulb lamp holder in claim 1, wherein the LED dies comprise at least two different colors LED dies.

10. The multi-directional bulb lamp holder in claim 10, wherein the LED dies comprises two or more LED dies with colors of red, green or blue.

11. The multi-directional bulb lamp holder in claim 1, wherein the LED dies are arranged in unequal intervals.

12. The multi-directional bulb lamp holder in claim 1, wherein the LED dies are electrically connected to the flexible substrate by wire bonding or die bonding.

13. The multi-directional bulb lamp holder in claim 1, further comprising a first light transmitting layer, the first light transmitting layer covers the LED dies.

14. The multi-directional bulb lamp holder in claim 13, wherein the first light transmitting layer further comprises a wavelength converting material, the wavelength converting material is mixed into the first light transmitting layer or coated on an outer surface of the first light transmitting layer.

15. The multi-directional bulb lamp holder in claim 14, wherein the wavelength converting material is phosphor, quantum wall film or quantum dot phosphor.

16. The multi-directional bulb lamp holder in claim 13, wherein each LED die is covered with a second light transmitting layer.

17. The multi-directional bulb lamp holder in claim 16, wherein the second light transmitting layer covers the LED dies integrally.

18. The multi directional bulb lamp holder in claim 17, wherein the second light transmitting layer further comprising a wavelength converting material, the wavelength converting material is mixed into the second light transmitting layer or coated on an outer surface of the first light transmitting layer.

19. The multi-directional bulb lamp holder in claim 13, further comprising a wavelength converting layer combined with the first light transmitting layer.

20. The multi-directional bulb lamp holder in claim 1, further comprising a heat dissipating body connected to the carrying body.
